(19) United States
(12) Patent Application Publication
(10) Pub. No.: US 2006/0119380 A1
(43) Pub. Date: Jun. 8, 2006

(54) Integrated circuit input/output signal termination with reduced power dissipation

(76) Inventor: Jason Gonzalez, Fort Collins, CO (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 11/005,784

(22) Filed: Dec. 7, 2004

(51) Int. Cl. H03K 19/003

(52) U.S. Cl. 326/30

(57) ABSTRACT

Systems and methods for providing input/output signal termination with reduced power dissipation on an integrated circuit die are invented and disclosed. One embodiment comprises a method for reducing on die power dissipation while providing on die signal termination that includes receiving a termination reference voltage at a first input of an integrated circuit die, applying the first signal to a single termination element coupled in series between the first input and a receiver input to generate a common node reference voltage, receiving a second signal at a second input of the integrated circuit die, and coupling the second signal to the receiver input.

### BACKGROUND

In integrated circuits, such as microprocessors, memories, and the like, signals may be routed for relatively long distances using transmission lines. A transmission line may be a bus, a printed circuit board trace, or other types of electrical conductors for transporting a signal. Typically, a printed circuit board trace has a characteristic impedance of between 50 and 75 ohms. In complementary metal-oxide semiconductor (CMOS) circuits, the input impedance of a gate of a CMOS transistor is usually very high. The receiving end, or far end, of the transmission line is typically connected to an input of a logic circuit, where the input impedance is higher than the characteristic impedance of the transmission line. When the impedance coupled to the far end of the transmission line is different than the impedance of the transmission line, the signal will be reflected back to the sending end. Depending on the sending end impedance, the signal may overshoot/undershoot a planned steady-state voltage for the logic state. The signal may be reflected back and forth many times between the near end and the far end, causing oscillatory behavior of the signal at both ends. This repeated overshooting and undershooting of the signal is commonly known as “ringing,” and results in reduced noise immunity and increased time for the signal to become, and remain, stable at the far end. Impedance matching is the practice of matching the impedance of the driver and/or the load to the characteristic impedance of the transmission line to reduce ringing and facilitate the most efficient transfer of signals.

As bus speeds increase above 100 MHz, impedance mismatches become a significant concern as timing margins are reduced as a result of the increased clock frequency. A number of different approaches have been used to account for impedance mismatches in electronic data systems. Some of these approaches include adding passive external elements (resistors, inductors, etc.); adjusting the drive strength of output drivers; and actively terminating signal transmission lines.

The joint electron device engineering council (JEDEC) solid-state technology association standards define input and output specifications independently of each other. Accordingly, drivers and receivers are defined independently from each other. First and second voltages for receivers are defined. A sample circuit model 10 is illustrated in FIG. 1. Circuit model 10 includes a transmitting integrated circuit (IC) 11 and a receiving IC 31 coupled to each other via a transmission line modeled by transmission line resistor 20. Transmitting IC 11 includes driver 16, pull-up resistor 12, and pull-down resistor 13. Driver 16 is coupled between V_{DD} and electrical ground. The series coupled pull-up resistor 12 and pull-down resistor 13 are similarly coupled between V_{DD} and ground. When the resistance values of the pull-up resistor 12 and the pull-down resistor 13 are equal, the voltage at output node 14 is V_{DD}/2 volts. Receiving IC 31 includes termination network 50 and receiver 36. The first reference voltage, V_{IN}, is applied at the receiver 36. The second reference, V_{DD}, is coupled to termination network 50. Termination network 50 includes a first resistor 52 and a second resistor 56 in series between V_{DD} and electrical ground. When the resistance values of first resistor 52 and second resistor 56 are equal, the first reference voltage, V_{IN}, is V_{DD}/2. This arrangement shunts a significant amount of current from the supply to the ground node at the input to the receiver 36. The addition of passive elements in a termination network requires printed circuit assembly area, consumes power and does not account for impedance variations due to variations in supply voltage, temperature, and age.

Other on-chip solutions require the use of separate test input/output (I/O) pads for determining suitable impedance matching. In one example, an external test pad is used to determine suitable pull-up circuit impedance whereas a separate additional test pad is used to determine suitable impedance matching for a pull-down circuit of the output buffer. The use of additional test pads and additional external resistors can impact power consumption, reliability, and cost.

Solutions that actively terminate transmission lines share many of the drawbacks of solutions that use external passive elements and solutions that adjust output drive strength. That is, active termination requires additional off chip elements, increases power consumption, and is susceptible to process, voltage, and temperature variations.

Therefore, it is desirable to introduce low-cost systems and methods for reducing power consumption in input/output circuits.

### SUMMARY

One embodiment of an integrated circuit die comprises first and second pads, a termination element, and a receiver. The first pad is coupled to a termination reference voltage generated external to the die. The termination element is coupled between the first pad and an input node of the receiver. The second pad is coupled to a transmission line external to the die. The transmission line is coupled to a driver output and the input node of the receiver.

One embodiment of a transceiver system for digital logic circuits comprises a printed circuit board, a package, and an integrated circuit die. The printed circuit board is configured to provide a termination reference voltage at an interface. The package is coupled to the interface and configured with a plurality of conductive links that traverse the package. A first conductive link comprises the termination reference voltage and a second conductive link comprises a data signal. The integrated circuit die is configured with a plurality of pads, a termination element, and a receiver. The pads transport input and output signals. The termination element is coupled in series between a first pad and an input node of the receiver. The first pad is coupled to the first conductive link. A second pad is coupled to the second conductive link and the input node.

Another embodiment describes a method for reducing on die power dissipation while providing on die signal termination. The method comprises receiving a termination reference voltage at a first input of an integrated circuit die, applying the first signal to a single termination element coupled in series between the first input and a receiver input to generate a common node reference voltage, receiving a second signal at a second input of the integrated circuit die, and coupling the second signal to the receiver input.

### BRIEF DESCRIPTION OF THE DRAWINGS

The present systems and methods for providing input/output signal termination with reduced power dissipation on an integrated circuit die, as defined in the claims, can be better understood with reference to the following drawings. The components within the drawings are not necessarily to scale relative to each other; emphasis instead is placed upon clearly illustrating the principles of the systems and methods.

FIG. 1 is a circuit schematic illustrating a prior art embodiment of signal termination on an integrated circuit.

FIG. 2 is a schematic diagram illustrating an embodiment of a transceiver system.

FIG. 3 is a circuit schematic illustrating an embodiment of an input/output signal termination with reduced power dissipation on the integrated circuit die of the transceiver system of FIG. 2.

FIG. 4 is a schematic diagram illustrating signal voltages as observed at an output of the receiver of FIG. 3.

FIG. 5 is a flow diagram illustrating an embodiment of a method for reducing on die power dissipation while providing on die input signal termination.

FIG. 6 is a flow diagram illustrating an embodiment of a method for terminating a signal received from an external driver.

### DETAILED DESCRIPTION

The present systems and methods provide an alternative for on-die input signal termination that can result in as much as a 5 fold reduction in on die power dissipation for input signal termination. The present circuit arrangement and termination method retains the signal integrity and timing benefits associated with signal termination techniques while using significantly less power.

Present integrated circuit signal transmission systems and methods for reducing on die power dissipation while providing on die signal termination supply a termination reference from an off die source to a single termination element coupled in series with an input of the designated receiver. The single termination element provides a linear termination impedance. An on die switch enables the termination to be selectable. By matching the equivalent resistance of the termination element with the pull-down and pull-up resistors in the output stage of the driver amplifying the input data signal, the overall power dissipated in signal termination at the receiver is reduced. Accordingly, the power to signal ratio is relaxed over that in conventional integrated circuits that use a termination network to generate a common-mode voltage at the input to the receiver. The reduced current loads that result allow designers to increase the logic density on the integrated circuit and use interconnecting packages that are less expensive to manufacture.

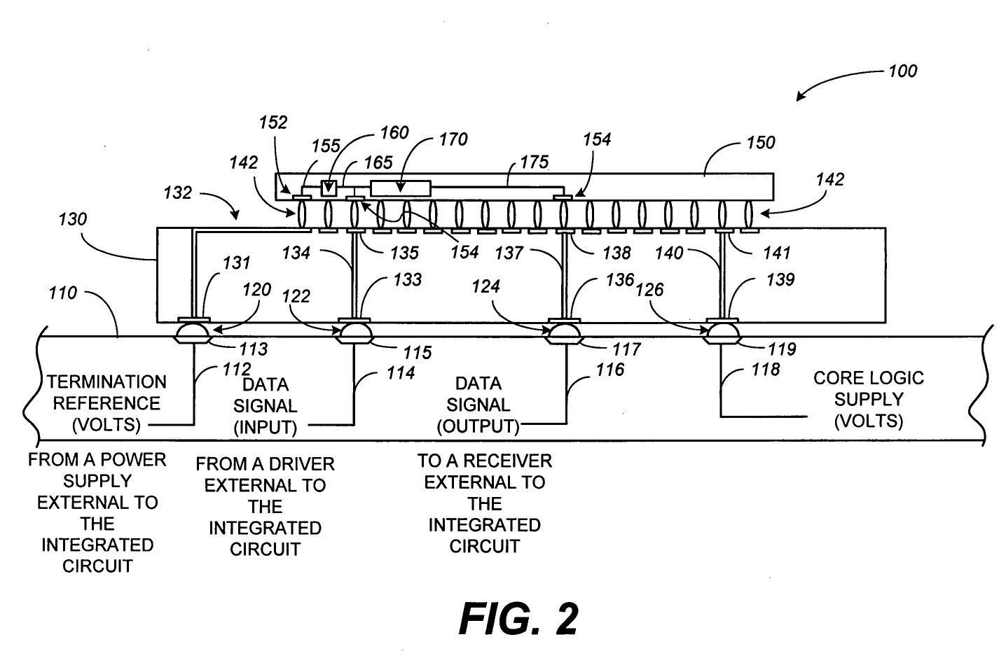

Turning to the drawings that illustrate various embodiments of systems and methods for reducing on die power dissipation while providing on die input signal termination, FIG. 2 is schematic diagram illustrating an embodiment of a transceiver system. Transceiver system 100 includes a printed circuit board 110, a package 130, and a receiving IC 150 illustrated as an integrated circuit die. Package 130 couples receiving IC 150 to printed circuit board 110. Coupled signals include a termination reference, a core logic supply, and input and output data signals.

Printed circuit board 110 provides the termination reference along conductor 112 to interface 113 and the core logic supply along conductor 118 to interface 119. One or both of the termination reference and the core logic supply can be generated via one or more power supplies coupled to printed circuit board 110. Alternatively, one or both of the termination reference and the core logic supply can be generated on printed circuit board 110.

Printed circuit board 110 further provides an input data signal along conductor 114 to interface 115. The input data signal is generated by a driver external to the receiving IC 150. Printed circuit board 110 is also configured to receive a data signal from receiving IC 150 via the package 130 at interface 117. The data signal is coupled to one or more destinations on or off printed circuit board 110 via conductor 116.

Package 130 is coupled to printed circuit board 110 via a plurality of conductive connections such as solder balls 120, 122, 124, and 126. Solder ball 120 connects interface 113 with pad 131 to couple the termination reference from the printed circuit board 110 to receiving IC 150. The termination reference traverses conductor 132 and conductor 142 before it is applied via first input 152 of the receiving IC 150. Solder ball 122 connects interface 115 with pad 133 to couple the input data signal from printed circuit board 110 to receiving IC 150. The input data signal traverses conductor 134 and pad 135 in package 130 before it is coupled to second input 154 of receiving IC 150. The output data signal is coupled from output 154 via conductor 142, pad 138, and conductor 137 to pad 136. Solder ball 124 connects interface 117 with pad 136 to couple the output data signal from receiving IC 150 to printed circuit board 110 where it can be forwarded to one or more destinations on or off the printed circuit board 110. Solder ball 126 connects interface 119 with pad 139 to couple the core logic supply from the printed circuit board 110 to receiving IC 150. The core logic supply traverses conductor 140 and pad 141 in package 130 before it is coupled to one or more core logic circuits (not shown) on receiving IC 150. Components of the package 130 can be implemented with known or to be developed manufacturing techniques. The various pads 131, 133, 135, 136, 138, 139, and 141, as well as the various conductors 132, 134, 137, 140 will be configured such that they can carry current delivered to and from the receiving IC 150 with an adequate margin.

The termination reference provided at first interface 154 is coupled to a single termination element 160 via conductor 155. The input data signal provided at second interface 154 is coupled to the output of the single termination element 160 and to the input of receiver 170 via conductor 165. The output of receiver 170 is coupled to output 154 via conductor 175. Components of the receiving IC 150 can be implemented with known or to be developed integrated circuit manufacturing techniques or technologies.

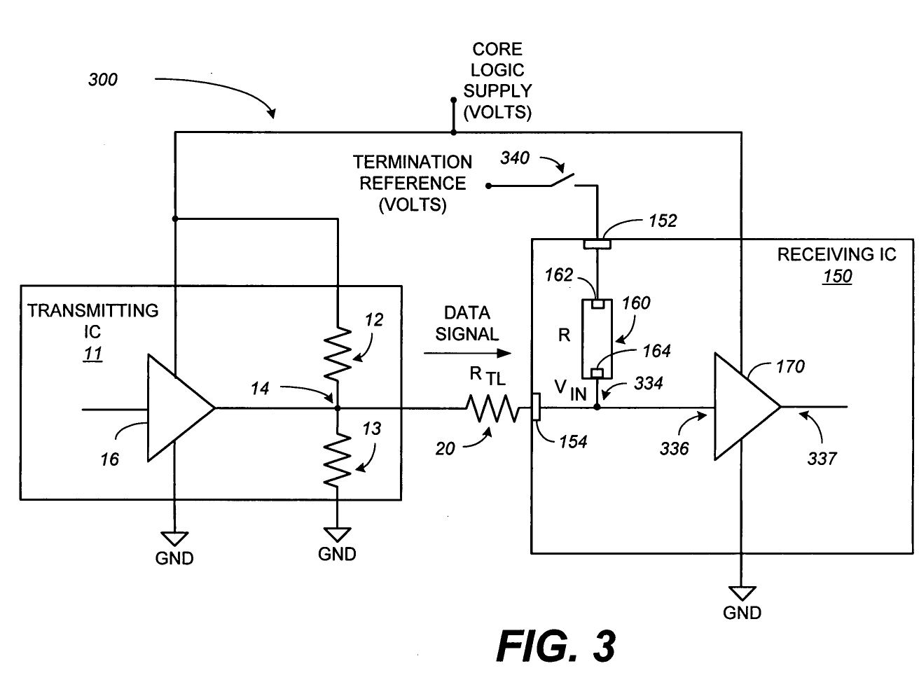

FIG. 3 is a circuit schematic 300 illustrating an embodiment of an input/output signal termination with reduced power dissipation on the receiving IC 150 (i.e., an integrated circuit die) of the transceiver system 100 of FIG. 2. Circuit schematic 300 includes a transmitting IC 11 and a receiving IC 150 coupled to each other via a transmission line modeled by transmission line resistor 20. Transmitting IC 11 includes driver 16, pull-up resistor 12, and pull-down resistor 13. Driver 16 is coupled between a core logic supply and electrical ground. The series coupled pull-up resistor 12 and pull-down resistor 13 are similarly coupled between the core logic supply and ground. When the resistance values of the pull-up resistor 12 and the pull-down resistor 13 are equal, the voltage at output node 14 is ½ the core logic supply voltage.

Receiving IC 150 includes a first input 152, a second input 154, single termination element 160, and receiver 170. Receiver 170 is configured with an input 336, an output 337, and is coupled between the core logic supply and electrical ground. Single termination element 160 is coupled in series between a termination reference and node 334 with input 162 proximal to the termination reference and output 164 proximal to node 334. Node 334 is coupled to second input 154 and receiver input 336. Single termination element 160 can include a single resistor, one or more selectable resistors, and or one or more transistors. When the resistance of single termination element 160 is substantially equal to the resistance value of pull-up resistor 12 and pull-down resistor 13 in transmitting IC 11 the signal transmitted from driver 16 to receiver 170 can meet the termination logic standards promulgated by the JEDEC with a significant reduction in on die power dissipation.

For example, a conventional signal transmission circuit with driver pull-up and pull-down resistors having resistance values of 45 ohms and receiver pull-up and pull-down resistance values of 90 ohms with an on die voltage of 2.75 volts supplied to the receiver termination network results in a termination current of 22.92 mA with 15.28 mA being grounded in the driver pull-down resistor and 7.64 mA being grounded via the receiver. Accordingly, the receiver termination network dissipates 52.53 mW and the driver dissipates an additional 10.50 mW. When the single termination element 160 of FIG. 3 is configured with an equivalent resistance of 45 ohms, and the off die generated termination reference is set to 1.375 volts the termination current is reduced to 15.28 mA. With this configuration, the receiving IC 150 and the transmitting IC 11 each dissipate 10.50 mW. Thus, the receiving IC 150 dissipates 42.03 mW less power than the conventional circuit arrangement.

Switch 340 is used to controllably apply the termination reference to the receiving IC 150. Switch 340 is opened and the termination reference removed from the receiving IC 150 for test operations (e.g., leakage, tri-state, electrostatic discharge sensitivity, etc.) and for functional operations when the receiver 150 is used as an output driver. Switch 340 is closed when receiving IC 150 is designated for receiving a data signal at the second input 154.

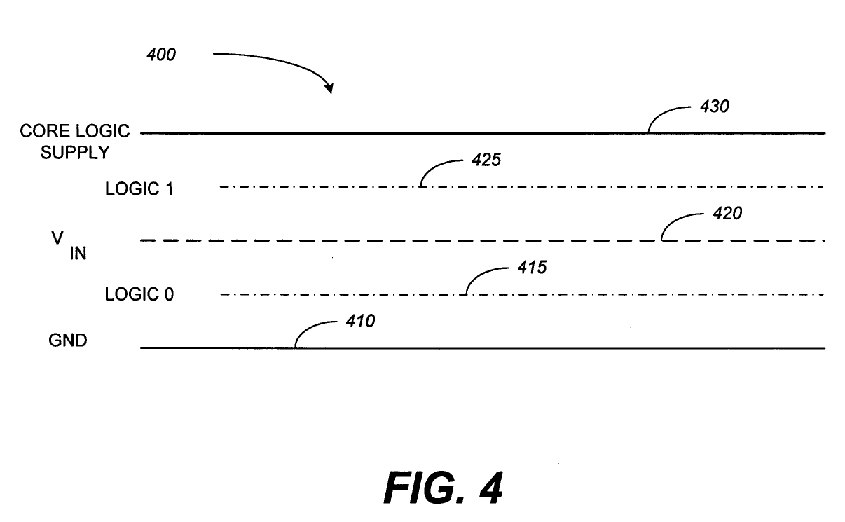

FIG. 4 is a diagram 400 illustrating signal voltage levels as observed at the receiver 170 of FIG. 3. As shown in diagram 400, signal voltages start at electrical ground represented by line 410. A common-mode reference voltage, V_{IN}, is represented by line 420, which is equidistant between electrical ground and the core logic supply voltage represented by line 430. As indicated in diagram 400, when the data signal from driver 16 pulls the common-mode reference voltage down to line 415, a logic value of 0 is recognized. On the other hand, when the data signal from driver 16 pulls the common-mode reference voltage up to line 425, a logic 1 is recognized. A termination voltage reference value can be selected such that the common-mode reference voltage is ½ of the core logic supply voltage. At that level, a logic 0 is recognized when the data signal is ¼ the voltage of the core logic supply and a logic 1 is recognized when the data signal is ¾ the voltage of the core logic supply.

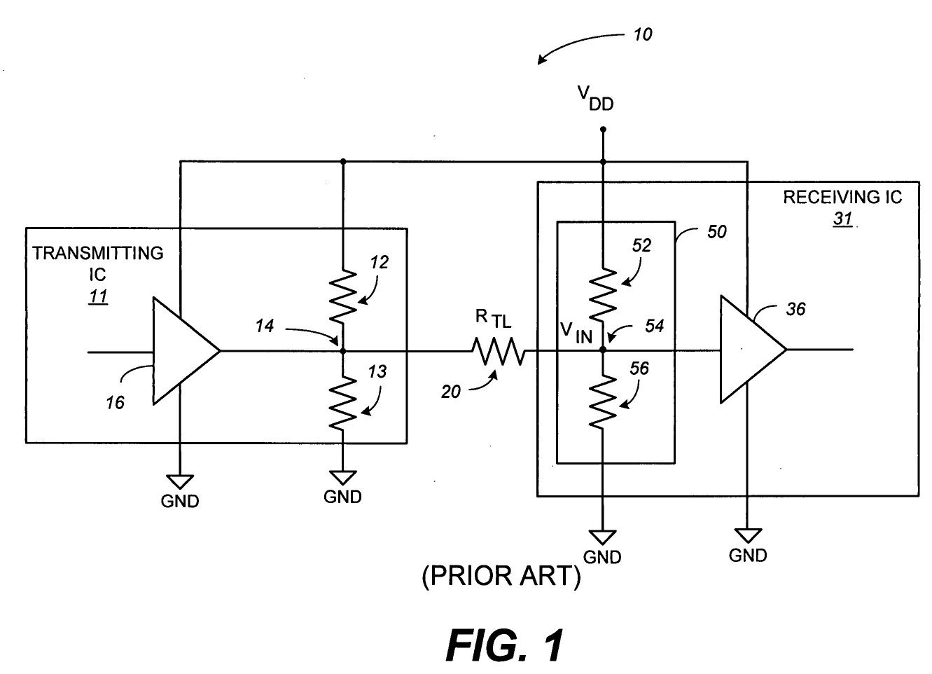

The signal voltage levels as observed at the receiver 170 of FIG. 3 are electrically equivalent to those at the output of the driver 16 in the conventional circuit model of FIG. 1. By providing the reference voltage external to the receiving IC 150, the power to signal ratio can be dramatically reduced. Because receiving IC 150 dissipates less power in terminating input signals than integrated circuits that use conventional termination networks, on die element density can be increased while using lighter packages that are less expensive to produce.

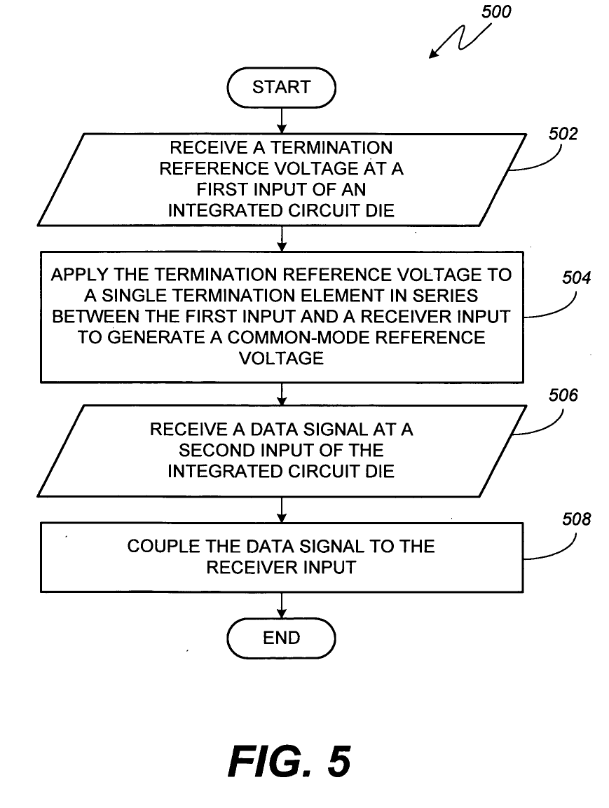

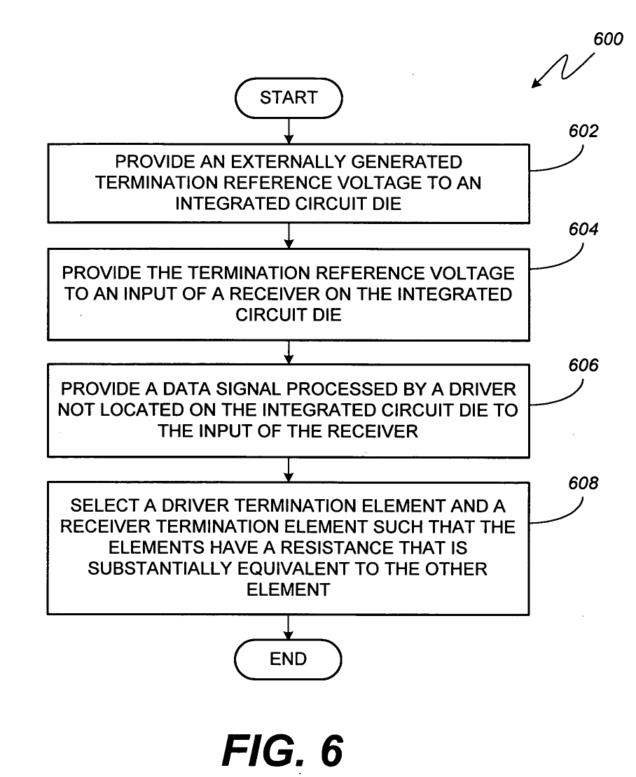

Any process descriptions or blocks in the flow diagrams illustrated in FIGS. 5 and 6 should be understood as representing steps in an associated process. Alternative implementations are included within the scope of the present methods for adjusting an output driver. For example, functions may be executed out-of-order from that shown or discussed, including substantially concurrently or in reverse order, depending on the functionality involved.

FIG. 5 is a flow diagram illustrating an embodiment of a method for reducing on die power dissipation while providing on die input signal termination. As illustrated in FIG. 5, method 500 begins with input/output block 502 where a termination reference voltage is received at a first input of an integrated circuit die. In block 504, the termination reference voltage is applied to a single termination element coupled in series between the first input and a receiver input to generate a common-mode reference voltage. In input/output block 506, a data signal is received at a second input of the integrated circuit die. In block 508, the data signal is coupled to the receiver input.

When the resistance values of the pull-up and pull-down resistors associated with a driver that is supplying the data signal to the receiver closely approximate the resistance value of the termination element, the power dissipated on the integrated circuit die of the receiver is significantly reduced from conventional receivers that use a termination network with a network element coupled between the receiver input and electrical ground.

FIG. 6 is a flow diagram illustrating an embodiment of a method 600 for terminating a signal received from an external driver. As shown in FIG. 6, method 600 begins with block 602 where an externally generated termination reference voltage is provided to an integrated circuit die. In block 604, the termination reference voltage is coupled to the input of a receiver on the integrated circuit die. In block 606, a data signal processed by a driver not located on the integrated circuit die is coupled to the input of the receiver. In block 608, a driver termination element and a receiver termination element are selected such that the elements have resistance values that are substantially equivalent to each other. The receiver termination element is applied in series between the termination reference voltage of block 602 and the input of the receiver.

The driver termination element is part of a voltage divider applied between the reference voltage and electrical ground. The voltage divider includes a pull-down resistor coupled between the driver output and electrical ground. The voltage divider also includes a pull-up resistor coupled between the core logic supply voltage and the driver output. When the data signal of block 604 is less than half the voltage level of termination reference, the pull-down resistor assists the driver in providing an amplified data signal to the receiver that is between the common-mode voltage of the receiver and electrical ground. When the data signal of block 604 is greater than half the voltage level of the termination reference, the pull-up resistor assists the driver in providing an amplified data signal to the receiver that is between the common-mode voltage of the receiver and the core logic supply voltage. When the resistance values of the pull-up and pull-down resistors closely approximates the resistance value of the receiver termination element, the power dissipated on the integrated circuit die of the receiver is significantly reduced from conventional receivers that use a termination network with a network element coupled between the receiver input and electrical ground.

It should be emphasized that the above-described embodiments are merely examples of implementations of the systems and methods for providing input/output signal termination with reduced power dissipation on an integrated circuit die. Many variations and modifications may be made to the above-described embodiments. All such modifications and variations are intended to be included herein within the scope of this disclosure and protected by the following claims.

What is claimed is:

1. A method for reducing on die power dissipation while providing on die signal termination, comprising:
receiving a termination reference voltage an input of an integrated circuit die;
applying the termination reference voltage to a single termination element coupled in series between the first input and a receiver input to generate a common mode reference voltage;
receiving a data signal at a second input of the integrated circuit die; and
coupling the data signal to the receiver input.

2. The method of claim 1, wherein receiving a termination reference voltage comprises receiving a direct coupled voltage from a package.

3. The method of claim 1, wherein receiving a termination reference voltage comprises receiving a direct coupled voltage from a printed circuit board.

4. The method of claim 1, wherein receiving a termination reference voltage comprises receiving a direct coupled voltage from a power supply external to the integrated circuit die.

5. The method of claim 1, wherein applying the termination reference voltage to a single termination element comprises coupling the termination reference voltage to an on die resistor.

6. The method of claim 1, wherein applying the termination reference voltage to a single termination element comprises coupling the first signal to an on die transistor.

7. The method of claim 1, wherein receiving a data signal comprises receiving the data signal from a driver external to the integrated circuit die.

8. The method of claim 7, wherein receiving a data signal comprises receiving the data signal from a driver comprising an element having a resistance substantially equivalent to the resistance of the single termination element.

9. An integrated circuit die, comprising:
a first pad coupled to a termination reference voltage generated external to the die;
a termination element having an input and an output, the input coupled in series to the first pad;
a receiver having an input node and an output node, the input node coupled to the output of the termination element; and
a second pad coupled to a transmission line external to the die, the transmission line having a first end coupled to a driver output and a second end proximal to the integrated circuit die, the second pad coupled to the input node of the receiver.

10. The integrated circuit die of claim 9, wherein the first pad is coupled to a termination reference voltage having a level that comprises a mid-point of the range of the receiver.

11. The integrated circuit die of claim 9, wherein the termination element comprises a resistor.

12. The integrated circuit die of claim 9, wherein the termination element comprises a transistor.

13. The integrated circuit die of claim 9, wherein the second pad coupled to a transmission line external to the die is coupled to a driver comprising an element having a resistance substantially equivalent to the resistance of the single termination element.

14. A system, comprising:
means for providing an externally generated termination reference voltage to an integrated circuit die;
means for providing the termination reference voltage to an input of a receiver located on the integrated circuit die; and
means for providing a signal processed by an external driver to the input of the receiver.

15. The system of claim 14, wherein the means for providing an externally generated termination reference voltage comprises means for electrically conducting the termination reference voltage from a printed circuit assembly to the integrated circuit die.

16. The system of claim 14, wherein the means for providing the termination reference voltage to an input of a receiver comprises a single termination element.

17. A transceiver system for digital logic circuits, comprising:
a printed circuit board configured to provide a termination reference voltage at an interface;
a package coupled to the interface and configured with a plurality of conductive links that traverse the package wherein a first conductive link comprises the termination reference voltage and a second conductive link comprises a data signal; and
an integrated circuit die configured with a plurality of pads configured to transport input and output signals, a termination element having an input and an output, the input coupled in series to a first pad, and a receiver having an input node coupled to the output of the termination element, wherein the first pad is coupled to the first conductive link and a second pad is coupled to the second conductive link and the input node.

18. The transceiver system of claim 17, wherein the package comprises a data signal processed on a device external to the integrated circuit die.

19. The transceiver system of claim 18, wherein the device external to the integrated circuit die comprises an element having a resistance substantially equivalent to the resistance of the termination element.

20. The integrated circuit die of claim 17, wherein the printed circuit board provides a termination reference voltage that approximates a mid-point of the range of the receiver.
